(19) United States
(12) Patent Application Publication
(10) Pub. No.: US 2024/0324241 A1
(43) Pub. Date: Sep. 26, 2024

(54) MAGNETIC MEMORY DEVICE

(71) Applicant: Kioxia Corporation, Tokyo (JP)

(72) Inventors: Masatoshi YOSHIKAWA, Setagaya Tokyo (JP); Tian LI, Yokohama Kanagawa (JP)

(21) Appl. No.: 18/594,394

(22) Filed: Mar. 4, 2024

(30) Foreign Application Priority Data
Mar. 23, 2023 (JP) 2023-047106

(51) Int. Cl. H10B 61/00; H10N 50/01; H10N 50/20

(52) U.S. Cl. CPC H10B 61/00; H10N 50/01; H10N 50/20

(57) ABSTRACT

According to one embodiment, there is provided a magnetic memory device including a first conductive layer; and a first magnetoresistive effect element and a second magnetoresistive effect element that each extends in a first direction, are provided apart from each other in a second direction crossing the first direction, and are each in contact with the first conductive layer, wherein the first conductive layer includes a first portion that does not overlap with any of the first magnetoresistive effect element and the second magnetoresistive effect element when viewed in the first direction, a second portion that overlaps with a central region of the first magnetoresistive effect element when viewed in the first direction, and a third portion that overlaps with an edge region of the first magnetoresistive effect element when viewed in the first direction.

### CROSS-REFERENCE TO RELATED APPLICATION

This application is based upon and claims the benefit of priority from Japanese Patent Application No. 2023-047106, filed Mar. 23, 2023, the entire contents of which are incorporated herein by reference.

### FIELD

Embodiments described herein relate generally to a magnetic memory device.

### BACKGROUND

A magnetic memory device using a magnetoresistive effect element as a storage element is known. As a method for writing data into the magnetoresistive effect element, various methods have been proposed. For example, as a method for writing data without directly flowing a current into the magnetoresistive effect element, a writing method using spin orbit torque is known.

### DESCRIPTION OF THE DRAWINGS

FIG. 1 is a block diagram illustrating an example of a configuration of a magnetic memory device according to a first embodiment.

FIG. 2 is a circuit diagram illustrating an example of a circuit configuration of a memory cell array according to the first embodiment.

FIG. 3 is a cross-sectional view illustrating an example of a cross-sectional structure of a part of a memory string according to the first embodiment.

FIG. 4 is a plan view illustrating two examples of shapes of a wiring and an element layer according to the first embodiment.

FIG. 5 is a cross-sectional view illustrating an example of a cross-sectional structure of a part of the memory string according to the first embodiment during manufacture.

FIG. 6 is a cross-sectional view illustrating an example of a cross-sectional structure of a part of the memory string according to the first embodiment during manufacture.

FIG. 7 is a cross-sectional view illustrating an example of a cross-sectional structure of a part of the memory string according to the first embodiment during manufacture.

FIG. 8 is a cross-sectional view illustrating an example of a cross-sectional structure of a part of the memory string according to the first embodiment during manufacture.

FIG. 9 is a cross-sectional view illustrating an example of a cross-sectional structure of a part of a memory string according to a modification of the first embodiment during manufacture.

FIG. 10 is a cross-sectional view illustrating an example of a cross-sectional structure of a part of the memory string according to the modification of the first embodiment during manufacture.

FIG. 11 is a cross-sectional view illustrating an example of a cross-sectional structure of a part of the memory string according to the modification of the first embodiment during manufacture.

FIG. 12 is a cross-sectional view illustrating an example of a cross-sectional structure of a part of a memory string according to a second embodiment.

FIG. 13 is a plan view illustrating two examples of shapes of a wiring and an element layer according to the second embodiment.

FIG. 14 is a cross-sectional view illustrating an example of a cross-sectional structure of a part of a memory string according to a modification of the second embodiment.

FIG. 15 is a cross-sectional view illustrating an example of a cross-sectional structure of a part of a memory string according to the third embodiment.

FIG. 16 is a cross-sectional view illustrating an example of a cross-sectional structure of a part of the memory string according to the third embodiment during manufacture.

FIG. 17 is a cross-sectional view illustrating an example of a cross-sectional structure of a part of the memory string according to the third embodiment during manufacture.

FIG. 18 is a cross-sectional view illustrating an example of a cross-sectional structure of a part of the memory string according to the third embodiment during manufacture.

FIG. 19 is a cross-sectional view illustrating an example of a cross-sectional structure of a part of the memory string according to the third embodiment during manufacture.

FIG. 20 is a cross-sectional view illustrating an example of a cross-sectional structure of a part of the memory string according to the third embodiment during manufacture.

FIG. 21 is a cross-sectional view illustrating an example of a cross-sectional structure of a part of the memory string according to the third embodiment during manufacture.

FIG. 22 is a cross-sectional view illustrating an example of a cross-sectional structure of a part of a memory string according to a fourth embodiment.

FIG. 23 is a cross-sectional view illustrating an example of a cross-sectional structure of a part of a memory string according to a modification of the fourth embodiment.

### DETAILED DESCRIPTION

Embodiments provide a magnetic memory device that reduces a write current.

In general, according to one embodiment, there is provided a magnetic memory device including a first conductive layer; and a first magnetoresistive effect element and a second magnetoresistive effect element that each extends in a first direction, are provided apart from each other in a second direction crossing the first direction, and are each in contact with the first conductive layer. The first conductive layer includes a first portion, a second portion, and a third portion. The first portion does not overlap with any of the first magnetoresistive effect element and the second magnetoresistive effect element when viewed in the first direction. The second portion overlaps with a central region of the first magnetoresistive effect element when viewed in the first direction. The third portion overlaps with an edge region of the first magnetoresistive effect element when viewed in the first direction.

Hereinafter, several embodiments will be described with reference to the accompanying drawings. In the following description, a common reference numeral is given to components having the same function and configuration. When distinguishing a plurality of components having a common reference numeral, subscripts are given to the common reference numeral to distinguish the plurality of components. When there is no particular need to distinguish between a plurality of components, only a common reference numeral is given to the plurality of components, and no subscripts are given to the plurality of components. The subscript is not limited to subscripts or superscripts, but includes, for example, a lowercase alphabet added to the end of a reference numeral, a symbol, and an index that means an arrangement.

In the specification, the magnetic memory device is, for example, a magnetoresistive random access memory (MRAM). The magnetic memory device includes a magnetoresistive effect element as a storage element. The magnetoresistive effect element is a variable resistance element that has a tunnel magnetoresistance effect due to a magnetic tunnel junction (MTJ). The magnetoresistive effect element is also called an MTJ element.

### 1. First Embodiment

A first embodiment will be described.

### 1.1 Configuration

First, a configuration of a magnetic memory device according to the first embodiment will be described.

### 1.1.1 Magnetic Memory Device

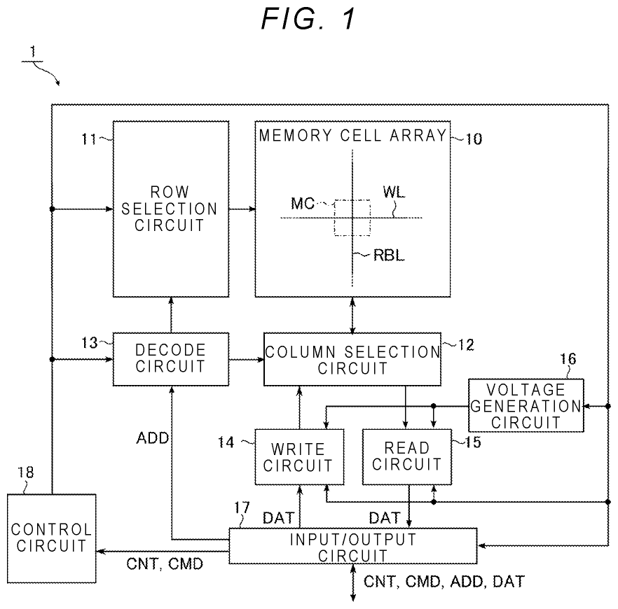

FIG. 1 is a block diagram illustrating an example of the configuration of the magnetic memory device according to the first embodiment. A magnetic memory device 1 includes a memory cell array 10, a row selection circuit 11, a column selection circuit 12, a decode circuit 13, a write circuit 14, a read circuit 15, a voltage generation circuit 16, an input/output circuit 17, and a control circuit 18.

The memory cell array 10 is a storage unit of data in the magnetic memory device 1. The memory cell array 10 includes a plurality of memory cells MC. Each of the plurality of memory cells MC is correlated with a set including a row and a column. The memory cells MC in the same row are correlated with the same word line WL. The memory cells MC in the same column are correlated with the same read bit line RBL.

The row selection circuit 11 is a circuit that selects a row of the memory cell array 10. The row selection circuit 11 is connected to the memory cell array 10 via a word line WL. Part of a decoding result (row address) of an address ADD from the decode circuit 13 is supplied to the row selection circuit 11. The row selection circuit 11 selects the word line WL corresponding to a row based on the part of the decoding result of the address ADD. In the following, the selected word line WL is referred to as a selected word line WL. Word lines WL other than the selected word line WL are referred to as non-selected word lines WL.

The column selection circuit 12 is a circuit that selects a column of the memory cell array 10. The column selection circuit 12 is connected to the memory cell array 10 via a read bit line RBL. Part of a decoding result (column address) of the address ADD from the decode circuit 13 is supplied to the column selection circuit 12. The column selection circuit 12 selects the read bit line RBL corresponding to a column based on the part of the decoding result of the address ADD. In the following, the selected read bit line RBL will be referred to as a selected bit line RBL. The read bit lines RBL other than the selected bit line RBL are referred to as non-selected bit lines RBL.

The decode circuit 13 is a decoder that decodes the address ADD from the input/output circuit 17. The decode circuit 13 supplies the decoding result of the address ADD to the row selection circuit 11 and the column selection circuit 12. The address ADD includes a column address and a row address.

The write circuit 14 includes, for example, a write driver (not illustrated). The write circuit 14 writes data into memory cells MC.

The read circuit 15 includes, for example, a sense amplifier (not illustrated). The read circuit 15 reads data from memory cells MC.

The voltage generation circuit 16 generates voltages for various operations of the memory cell array 10 using a power supply voltage provided from outside (not illustrated) of the magnetic memory device 1. The voltage generation circuit 16 generates various voltages necessary for write operations and outputs the voltages to the write circuit 14. The voltage generation circuit 16 generates various voltages necessary for read operations and outputs the voltages to the read circuit 15.

The input/output circuit 17 controls communication with the outside of the magnetic memory device 1. The input/output circuit 17 transfers the address ADD from the outside of the magnetic memory device 1 to the decode circuit 13. The input/output circuit 17 transfers a command CMD from the outside of the magnetic memory device 1 to the control circuit 18. The input/output circuit 17 transmits and receives various control signals CNT between the outside of the magnetic memory device 1 and the control circuit 18. The input/output circuit 17 transfers data DAT from the outside of the magnetic memory device 1 to the write circuit 14, and outputs data DAT transferred from the read circuit 15 to the outside of the magnetic memory device 1.

The control circuit 18 includes, for example, a processor such as a central processing unit (CPU), a read only memory (ROM), and a random access memory (RAM). The control circuit 18 controls operations of the row selection circuit 11, the column selection circuit 12, the decode circuit 13, the write circuit 14, the read circuit 15, the voltage generation circuit 16, and the input/output circuit 17 in the magnetic memory device 1 based on the control signal CNT and the command CMD.

### 1.1.2 Memory Cell Array

Next, a configuration of the memory cell array of the magnetic memory device according to the first embodiment will be described.

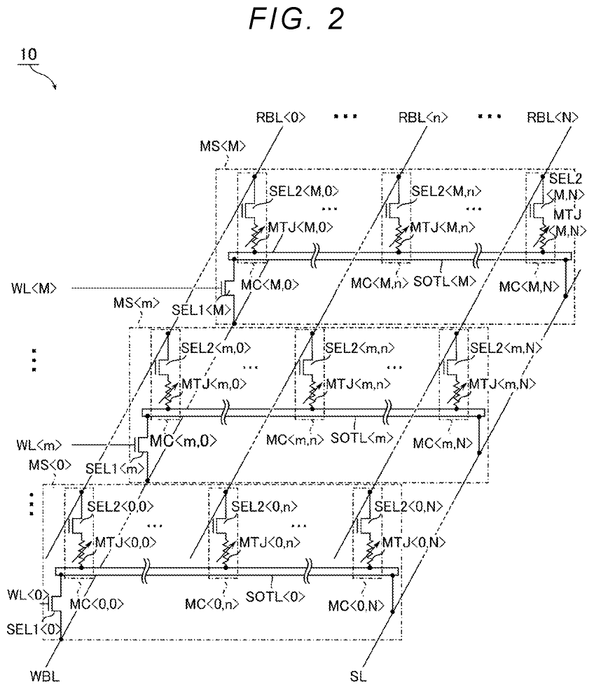

FIG. 2 is a circuit diagram illustrating an example of a circuit configuration of the memory cell array according to the first embodiment. In FIG. 2, each of the word lines WL and read bit lines RBL is classified and illustrated by a subscript including an index (“< >”).

The memory cell array 10 includes a plurality of word lines WL, a plurality of read bit lines RBL, a write bit line WBL, a source line SL, and a plurality of memory strings MS. The plurality of word lines WL include (M+1) word lines WL<0>, . . . , WL<m>, . . . , and WL<M>. M is an integer of 1 or more (0≤m≤M). The example of FIG. 2 illustrates a case where M is an integer of 1 or more, but is not limited thereto. For example, M may be 0. The plurality of read bit lines RBL include (N+1) read bit lines RBL<0>, . . . , RBL<n>, . . . , and RBL<N>. N is an integer of 1 or more (0≤n≤N).

The plurality of memory strings MS include (M+1) memory strings MS<0>, . . . , MS<m>, . . . , and MS<M>. The memory strings MS<0> to MS<M> are correlated with the word lines WL<0>to WL<M>, respectively. Each of the memory strings MS<0> to MS<M> has the same configuration. In the following, the memory string MS<m> will be described as an example.

The memory string MS<m> includes a switching element SEL1<m>, a wiring SOTL<m>, and (N+1) memory cells MC<m,0>, , MC<m,n>, . . . , and MC<m,N>.

The switching element SEL1<m> is a three-terminal type switching element, such as a MOSFET. Specifically, the switching element SEL1<m> has a first end connected to the wiring SOTL<m>, a second end connected to the write bit line WBL, and a control end connected to the word line WL<m>.

The wiring SOTL<m> has a first end connected to the first end of the switching clement SEL1<m>, a second end connected to the source line SL, and a central portion between the first and second ends. At the central portion of the wiring SOTL<m>, (N+1) memory cells MC<m,0>, . . . , MC<m,n>, . . . , and MC<m,N> are connected apart from each other. In the following, a portion of the central portion of the wiring SOTL<m> that is connected to any one of the memory cells MC<m,0> to MC<m,N> is also referred to as a “cell portion”. A portion between two adjacent cell portions of the central part of the wiring SOTL<m> is also referred to as a “wiring portion”. Each cell portion of the wiring SOTL<m> has a first end connected to the write bit line WBL via the switching element SEL1<m> and a second end connected to the source line SL.

The memory cells MC<m,0> to MC<m,N> are correlated with the read bit lines RBL<0> to RBL<N>, respectively. Each of the memory cells MC<m,0> to MC<m,N> has the same configuration. In the following, the memory cell MC<m,n> will be described as an example.

The memory cell MC<m,n> includes a cell portion corresponding to the memory cell MC<m,n> of the wiring SOTL<m>, a switching element SEL2<m,n>, and a magnetoresistive effect element MTJ<m,n>.

The switching element SEL2<m,n>is, for example, a three-terminal type switching element such as a MOSFET. The switching element SEL2<m,n> has a first end connected to the magnetoresistive effect element MTJ<m,n>, a second end connected to the read bit line RBL<n>, and a control end.

The magnetoresistive effect element MTJ<m,n> connects the switching element SEL2<m,n> and a cell portion of the wiring SOTL<m> that corresponds to the memory cell MC<m,n> in series. The magnetoresistive effect element MTJ<m,n> is a variable resistance element. The magnetoresistive effect element MTJ<m,n> functions as a storage element that stores data in a nonvolatile manner by changing the resistance state thereof.

As described above, each memory string MS includes (N+1) memory cells MC connected to one wiring SOTL. Therefore, the memory cell array 10 includes (M+1) memory strings MS, and, accordingly, includes (M+1)×(N+1) memory cells MC<0,0>, . . . , MC<0,n>, . . . , MC<0,N>, . . . , MC<m,0>, . . . , MC<m,n>, . . . , MC<m,N>, . . . , MC<M,0>, . . . , MC<M,n>, . . . , and MC<M,N>.

### 1.1.3 Memory String

Next, a configuration of the memory string of the magnetic memory device according to the first embodiment will be described. In the following, a plane parallel to a surface of a substrate on which the memory cell array 10 is provided is referred to as an XY plane. As used herein, a direction in which the memory cell array 10 is provided with respect to the substrate surface is defined as a Z-direction or an upward direction. The directions that intersect with each other in the XY plane are defined as an X-direction and a Y-direction.

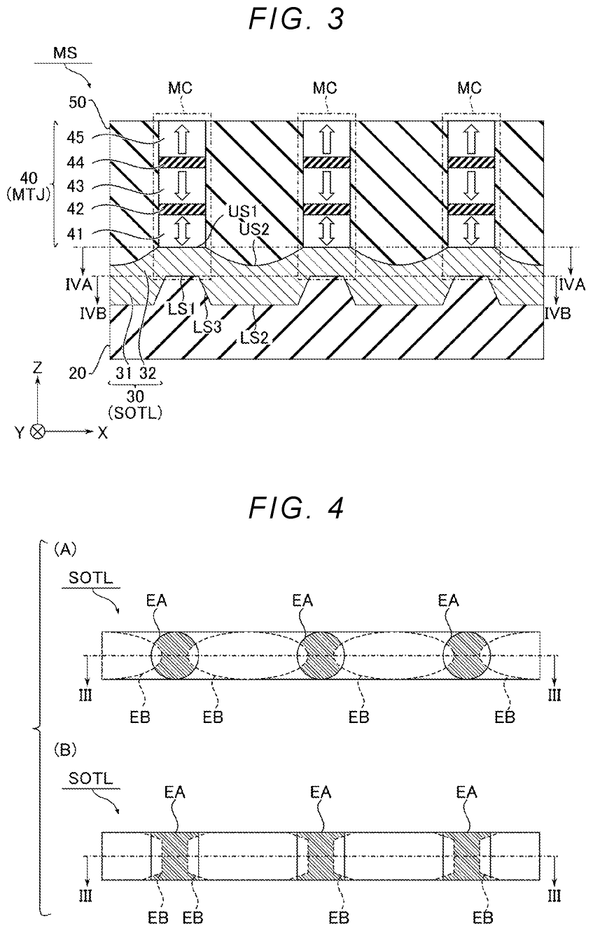

FIG. 3 is a cross-sectional view illustrating an example of a cross-sectional structure of a part of a memory string according to the first embodiment. In FIG. 3, a part of one wiring SOTL and three memory cells MC connected to the part of the wiring SOTL are illustrated in one memory string MS. As illustrated in FIG. 3, the memory string MS includes a conductive layer 30 and a plurality of clement layers 40. For simplicity, one of a plurality of element layers is also sometimes referred to herein as “the element layer.”

An insulator layer 20 is provided above the substrate (not illustrated). The conductive layer 30 is provided on an upper surface of the insulator layer 20. The conductive layer 30 extends in the X-direction. The conductive layer 30 is used as the wiring SOTL. A portion of the conductive layer 30 that overlaps with the element layer 40 when viewed in the Z-direction is used as the cell portion. A portion of the conductive layer 30 that does not overlap with the element layer 40 when viewed in the Z-direction is used as the wiring portion.

The conductive layer 30 is a continuous film that contains heavy metal having non-magnetism and conductivity. The conductive layer 30 contains at least one element selected from tantalum (Ta), tungsten (W), rhenium (Re), ruthenium (Ru), rhodium (Rh), palladium (Pd), silver (Ag), copper (Cu), osmium (Os), iridium (Ir), platinum (Pt), gold (Au), manganese (Mn), lead (Pb), bismuth (Bi), antimony (Sb), tellurium (Te), selenium (Se), and polonium (Po), as heavy metal. The elements contained as heavy metals in the conductive layer 30 may include oxides, nitrides, or sulfides. When tantalum (Ta) or tungsten (W) is contained, a structure of the element is preferably a β structure. For the conductive layer 30, a conductive oxide such as ruthenium oxide (RuO₂) or iridium oxide (IrO₂) may be used. For the conductive layer 30, a dichalcogenide transition metal having a two-dimensional layered structure such as WTe₂, WS₂, WSc₂, and the like may be used. The conductive layer 30 may be formed from a single layer containing the materials described above, or may be formed by stacking a plurality of layers containing the materials described above. The conductive layer 30 generates spin mainly from the spin Hall effect by a current flowing inside. The conductive layer 30 may generate spin torque from the spin splitter effect, spin torque from the Rashba effect, and the like. Such spin torques are collectively called spin orbit torque (SOT). The spin orbit torque acts on a portion of the element layer 40 that is in contact with the conductive layer 30.

The lower surface of the conductive layer 30 includes a first lower surface LS1 that is substantially parallel to the XY plane, a second lower surface LS2 that is substantially parallel to the XY plane and located below the first lower surface LS1, and a third lower surface LS3 connecting the first lower surface LS1 and the second lower surface LS2. The first lower surface LS1 and the second lower surface LS2 are arranged to be repeated alternately in the X-direction. The upper surface of the conductive layer 30 includes a first upper surface US1 that is substantially parallel to the XY plane and a second upper surface US2 located below the first upper surface US1. The first upper surface US1 and the second upper surface US2 are arranged to be repeated alternately in the X-direction.

FIG. 4 is a plan view illustrating two examples of shapes of a wiring and an element layer according to the first embodiment. In FIG. 4, a line of intersection between the IVA-IVA plane of FIG. 3 and the conductive layer 30 (that is, the boundary between the first upper surface US1 and the second upper surface US2 when viewed in the Z-direction) is illustrated as a solid line EA. In FIG. 4, a line of intersection between the IVB-IVB plane in FIG. 3 and the conductive layer 30 (that is, the boundary between the first lower surface LS1 and the third lower surface LS3 when viewed in the Z-direction) is illustrated as a dotted line EB. In FIG. 4, a portion of the first upper surface US1 that does not overlap with a region including the second lower surface LS2 and third lower surface LS3 when viewed in the Z-direction (that is, a portion that overlaps with the first lower surface LS1) is illustrated as hatched. The cross section illustrated in FIG. 3 is the cross section of the memory string MS taken along line III-III illustrated in FIG. 4.

In the upper part (A) of FIG. 4, as a first example, a case is illustrated in which the solid line EA forms a circle and the dotted line EB forms an oval. That is, when viewed in the Z-direction, the first upper surface US1 has a circular shape, and the region including the second lower surface LS2 and the third lower surface LS3 has an oval shape. In the example illustrated in the upper part (A) of FIG. 4, the solid line EA and the dotted line EB intersect. That is, a part of the first upper surface US1 overlaps with the region including the second lower surface LS2 and the third lower surface LS3 when viewed in the Z-direction.

In the lower part (B) of FIG. 4, as a second example, a case is illustrated in which the solid line EA forms a square and the dotted line EB forms substantially a rectangle. That is, when viewed in the Z-direction, the first upper surface US1 has a square shape, and the region including the second lower surface LS2 and the third lower surface LS3 has a substantially rectangular shape. In the example illustrated in the lower part (B) of FIG. 4, the solid line EA and the dotted line EB intersect. That is, a part of the first upper surface US1 overlaps with the region including the second lower surface LS2 and the third lower surface LS3 when viewed in the Z-direction.

From the point of view of the overlap between the element layer 40 and the conductive layer 30, the solid line EA can also be regarded as a region where the element layer 40 and the conductive layer 30 overlap when viewed in the Z-direction. From such point of view, it can be said that the region including the second lower surface LS2 and the third lower surface LS3 overlaps with an edge region of the element layer 40 when viewed in the Z-direction, but does not overlap with a central region thereof.

Referring to FIG. 3 again, the wiring SOTL will be described.

A film thickness of the conductive layer 30 is the thinnest in the portion where the first lower surface LS1 and the first upper surface US1 overlap (the portion which overlaps with the central portion of the element layer 40) when viewed in the Z-direction. The film thickness of the conductive layer 30 in the portion where the third lower surface LS3 and the first upper surface US1 overlap (the portion that overlaps with the edge portion of the element layer 40, which also overlaps with the second lower surface LS2 according to some embodiments) when viewed in the Z-direction is thicker than the film thickness of the conductive layer 30 in a portion where the first lower surface LS1 and the first upper surface US1 overlap (the portion which overlaps with the central portion of the element layer 40) when viewed in the Z-direction. The film thickness of the conductive layer 30 in the portion where the second lower surface LS2 and the second upper surface US2 overlap (a portion that does not overlap with element layer 40) when viewed in the Z-direction is thicker than the film thickness of the conductive layer 30 in a portion where the third lower surface LS3 and the first upper surface US1 overlap (the portion which overlaps with the edge portion of the element layer 40) when viewed in the Z-direction. The film thickness of the conductive layer 30 is the thickest in a portion where the second lower surface LS2 and the second upper surface US2 overlap (the portion which does not overlap with the element layer 40) when viewed in the Z-direction. That is, the film thickness of the wiring portion of the wiring SOTL is thicker than the film thickness of the cell portion.

The conductive layer 30 can also be said to have a stacked structure of conductive layers 31 and 32. The conductive layer 31 is a portion of the conductive layer 30 below the first lower surface LS1. The conductive layer 32 is a portion of the conductive layer 30 above the first lower surface LS1.

On the first upper surface US1 of the conductive layer 30, the element layer 40 is provided. The element layer 40 has a columnar shape extending in the Z-direction. The lower surface of the element layer 40 and the first upper surface US1 of the conductive layer 30 are flush with each other. The side surfaces of the element layer 40 are covered with an insulator layer 50.

The element layer 40 is used as the magnetoresistive effect element MTJ. Specifically, the element layer 40 includes a ferromagnetic layer 41, a nonmagnetic layer 42, a ferromagnetic layer 43, a nonmagnetic layer 44, and a ferromagnetic layer 45. The ferromagnetic layer 41, the nonmagnetic layer 42, the ferromagnetic layer 43, the nonmagnetic layer 44, and the ferromagnetic layer 45 are stacked in this order from bottom to top. That is, the element layer 40 extends in the Z-direction.

The ferromagnetic layer 41 is in contact with the first upper surface US1 of the conductive layer 30. The ferromagnetic layer 41 is a conductive film having ferromagnetism. The ferromagnetic layer 41 has a direction for an axis of easy magnetization in a direction perpendicular to the film surface (Z-direction). The spin orbit torque generated in the conductive layer 30 acts on the ferromagnetic layer 41. The ferromagnetic layer 41 is formed such that the magnetization direction thereof is reversed when spin orbit torque of a predetermined magnitude acts thereon.

The ferromagnetic layer 41 is generally a ferromagnetic layer using any element selected from cobalt (Co), iron (Fc), and nickel (Ni). Cobalt iron (CoFe) alloy, iron (Fe), cobalt iron boron (CoFeB), iron boron (FeB), cobalt boron (CoB), cobalt iron nickel boron (CoFeNiB), and the like are typical ferromagnetic layers having perpendicular magnetization. Such elements have a body-centered cubic structure (BCC structure). Examples of elements that can replace boron (B) include phosphorus (P) and carbon (C). A magnetic material such as CoFeB described above generates perpendicular magnetic anisotropy at the interface by coming into contact with an oxide having a NaCl (001) structure. A typical example is a MgO(001)/CoFeB stacked film or the like.

On the upper surface of the ferromagnetic layer 41, the nonmagnetic layer 42 is provided. The nonmagnetic layer 42 is an insulating film having non-magnetism. The nonmagnetic layer 42 is used as a tunnel barrier layer. The nonmagnetic layer 42 is provided between the ferromagnetic layer 41 and the ferromagnetic layer 43, and forms a magnetic tunnel junction with the two ferromagnetic layers. That is, a magnetoresistive effect occurs at the magnetic tunnel junction. When an initial amorphous layer such as cobalt iron boron (CoFeB) is used as an interface layer of the ferromagnetic layer 41, the nonmagnetic layer 42 functions as a seed material that becomes a core for growing a crystalline film from the interface with the ferromagnetic layer 41 in a crystallization process of the ferromagnetic layer 41. Similarly, when cobalt iron boron (CoFeB) is used as the interface layer of the ferromagnetic layer 43, the nonmagnetic layer 42 functions as a seed material for the ferromagnetic layer 43. Here, the initial amorphous layer is a layer that is in an amorphous state immediately after film formation and is crystallized after annealing treatment. The nonmagnetic layer 42 has a tetragonal or cubic structure in which the film surface is oriented in the (001) plane. A typical example of the oxide used for the nonmagnetic layer 42 is magnesium oxide (MgO). Other examples of oxides used in the nonmagnetic layer 42 include magnesium aluminum oxide (MgAlO), magnesium gallium oxide (MgGaO), and magnesium zinc oxide (MgZnO). The case where magnesium oxide (MgO) is applied will be described below. Magnesium oxide (MgO) has a NaCl structure. When magnesium oxide (MgO) is used for the nonmagnetic layer 42, the (001) interface of magnesium oxide (MgO) and the (001) interface of cobalt iron boron (CoFeB) are matched and crystals are grown by annealing. Therefore, cobalt iron boron (CoFeB) becomes a (001) oriented body-centered cubic structure.

On the upper surface of the nonmagnetic layer 42, the ferromagnetic layer 43 is provided. The ferromagnetic layer 43 is a conductive film having ferromagnetism. The ferromagnetic layer 43 is used as a reference layer. The ferromagnetic layer 43 has a direction for an axis of easy magnetization in a direction perpendicular to the film surface (Z-direction). The magnetization direction of the ferromagnetic layer 43 is fixed. The “magnetization direction is fixed” means that the magnetization direction is not changed by a torque large enough to reverse the magnetization direction of the ferromagnetic layer 41. In the example of FIG. 3, the magnetization direction of the ferromagnetic layer 43 is directed to the direction of the ferromagnetic layer 41. Generally, the ferromagnetic layer 43 includes an interface layer. As the interface layer of the ferromagnetic layer 43, an initial amorphous layer such as cobalt iron boron (CoFeB) is used. An auxiliary ferromagnetic layer is in contact with a surface of the cobalt iron boron (CoFeB) layer that is on a side opposite to a surface thereof that is in contact with the magnesium oxide (MgO) layer. The auxiliary ferromagnetic layer includes, for example, at least one alloy film selected from cobalt platinum (CoPt), cobalt nickel (CoNi), and cobalt palladium (CoPd). As the auxiliary ferromagnetic layer, a stacked film such as a Co/Pt stacked film or a Co/Pd stacked film may also be used. The cobalt iron boron (CoFeB) layer serving as the initial amorphous layer is used by being stacked with the CoPt, CoPd, Co/Pt stacked film, Co/Pd stacked film, and the like described above. Here, in the interface layer of the ferromagnetic layer 43, for example, in the CoFeB layer described above, a (001) oriented MgO layer is formed on a side closer to the nonmagnetic layer 42 than other layers.

On the upper surface of the ferromagnetic layer 43, the nonmagnetic layer 44 is provided. The nonmagnetic layer 44 is a conductive film having non-magnetism. The nonmagnetic layer 44 is used as a spacer layer. The nonmagnetic layer 44 is made of, for example, an element selected from ruthenium (Ru), osmium (Os), rhodium (Rh), iridium (Ir), and chromium (Cr), or an alloy thereof.

On the upper surface of the nonmagnetic layer 44, the ferromagnetic layer 45 is provided. The ferromagnetic layer 45 is a conductive film having ferromagnetism. The ferromagnetic layer 45 is used as a shift canceling layer. The ferromagnetic layer 45 has a direction for an axis of easy magnetization in a direction perpendicular to the film surface (Z-direction). The ferromagnetic layer 45 includes at least one alloy layer selected from, for example, cobalt platinum (CoPt), cobalt palladium (CoPd), cobalt palladium platinum (CoPdPt), and cobalt chromium platinum (CoCrPt). As the ferromagnetic layer 45, a stacked film such as a Co/Pt stacked film, a Co/Pd stacked film, a Co/Ni stacked film, and the like may also be used.

The ferromagnetic layer 43 and the ferromagnetic layer 45 are anti-ferromagnetically coupled by the nonmagnetic layer 44. That is, the ferromagnetic layer 43 and the ferromagnetic layer 45 are coupled to have magnetization directions anti-parallel to each other. Such antiferromagnetic magnetic coupling between the ferromagnetic layer 43, the nonmagnetic layer 44, and the ferromagnetic layer 45 is called synthetic anti-ferromagnetic (SAF) coupling. Due to the SAF coupling state, the ferromagnetic layer 45 can offset the influence of the leakage magnetic field of the ferromagnetic layer 43 on the change in the magnetization direction of the ferromagnetic layer 41, and reduce the influence of the substantial leakage magnetic field of the ferromagnetic layer 43 on the ferromagnetic layer 41.

Up to here, a case has been described in which the ferromagnetic layers 41, the ferromagnetic layers 43, and the ferromagnetic layers 45 have a direction for an axis of easy magnetization in a direction perpendicular to the film surface (Z-direction). However, the ferromagnetic layers 41, the ferromagnetic layers 43, and the ferromagnetic layers 45 may instead have a direction for an axis of easy magnetization in a direction parallel to the film surface (Y-direction).

The magnetoresistive effect element MTJ can take either a low resistance state or a high resistance state depending on whether a relative relationship between the magnetization directions of the storage layer and the reference layer is parallel or anti-parallel. In the magnetic memory device 1, the magnetization direction of the storage layer with respect to the magnetization direction of the reference layer is controlled without flowing a write current through such a magnetoresistive effect element MTJ. Specifically, a writing method that utilizes spin orbit torque generated by flowing a current through the wiring SOTL is adopted.

When a write current Ic0 of a certain magnitude is made to flow through the wiring SOTL in the Y-direction, the relative relationship between the magnetization directions of the storage layer and the reference layer becomes parallel. In the parallel state, a resistance value of the magnetoresistive effect element MTJ becomes the lowest, and the magnetoresistive effect element MTJ is set to the low resistance state. The low resistance state is called a “P (parallel) state” and is defined as a state of data “0”, for example.

When a write current Ic1 is made to flow through the wiring SOTL in the opposite direction to the write current Ic0, the relative relationship between the magnetization directions of the storage layer and the reference layer becomes anti-parallel. In the anti-parallel state, the resistance value of magnetoresistive effect element MTJ becomes the highest, and the magnetoresistive effect element MTJ is set to the high resistance state. The high resistance state is called an “AP (anti-parallel) state” and is defined as a state of data “1”, for example.

A method of defining data “1” and data “0” is not limited to the example described above. For example, the P state may be defined as data “1” and the AP state may be defined as data “0”.

### 1.2 Manufacturing Method

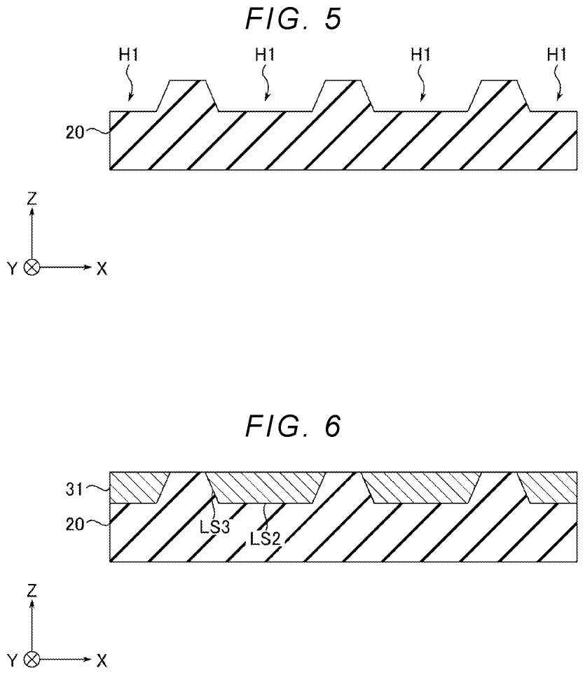

FIGS. 5 to 8 are cross-sectional views illustrating an example of a cross-sectional structure of the memory string according to the first embodiment during manufacture.

As illustrated in FIG. 5, a plurality of holes HI are formed on the upper part of the insulating layer 20 by anisotropic etching. For example, reactive ion etching (RIE) is used for the anisotropic etching in the present step.

Next, as illustrated in FIG. 6, a conductive layer is provided on the upper surface of the insulator layer 20. The conductive layer contains the same material as the conductive layer 30. A portion of the conductive layer above the portion where the plurality of holes H1 are located is removed by, for example, chemical mechanical polishing (CMP). As a result, a plurality of conductive layers 31 are formed to fill the plurality of holes H1. For simplicity, one of a plurality of conductive layers is also sometimes referred to herein as “the conductive layer.” A part of the upper surface of the conductive layer 31 is provided to overlap with an edge of the region where the magnetoresistive effect element MTJ is provided when viewed in the Z-direction. The bottom surface and side surface of each of the plurality of conductive layers 31 correspond to the second lower surface LS2 and the third lower surface LS3 of the wiring SOTL, respectively.

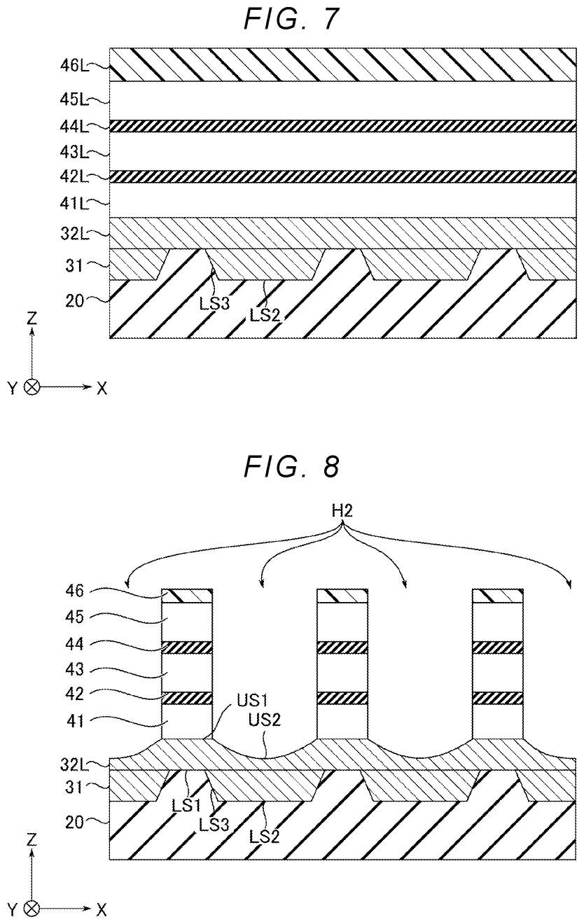

Next, as illustrated in FIG. 7, on the upper surfaces of the insulating layer 20 and the conductive layer 31, a conductive layer 32L, a ferromagnetic layer 41L, a nonmagnetic layer 42L, a ferromagnetic layer 43L, a nonmagnetic layer 44L, a ferromagnetic layer 45L, and a mask 46L are stacked in this order. Similar to the conductive layer 31, the conductive layer 32L contains the same material as the conductive layer 30. The ferromagnetic layer 41L contains the same material as the ferromagnetic layer 41. The nonmagnetic layer 42L contains the same material as the nonmagnetic layer 42. The ferromagnetic layer 43L contains the same material as the ferromagnetic layer 43. The nonmagnetic layer 44L contains the same material as the nonmagnetic layer 44. The ferromagnetic layer 45L contains the same material as the ferromagnetic layer 45.

As illustrated in FIG. 8, the ferromagnetic layer 41L, the nonmagnetic layer 42L, the ferromagnetic layer 43L, the nonmagnetic layer 44L, and the ferromagnetic layer 45L are etched by anisotropic etching to form a plurality of stacked bodies. Each of the plurality of stacked bodies includes the ferromagnetic layer 41, the nonmagnetic layer 42, the ferromagnetic layer 43, the nonmagnetic layer 44, and the ferromagnetic layer 45 stacked in this order from bottom to top. The plurality of stacked bodies are arranged apart from each other when viewed in the Z-direction. For example, ion beam etching (IBE) is used for the anisotropic etching in the current step.

One continuous hole H2 is formed between the plurality of stacked bodies. The conductive layer 32L is exposed on a bottom surface of the hole H2. The conductive layer 32L exposed in the hole H2 is etched simultaneously with upper layers by IBE. Therefore, a height of a portion of the upper surface of the conductive layer 32L that is exposed in the hole H2 is lower than a height of a portion in contact with the element layer 40. The portion of the upper surface of the conductive layer 32L that is in contact with the element layer 40 is the first upper surface US1 of the wiring SOTL. In the portion of the upper surface of the conductive layer 32L that is exposed in the hole H2, portions between the element layers 40 arranged in the X-direction correspond to the second upper surface US2 of the wiring SOTL.

Thereafter, a plurality of conductive layers 32 are formed by dividing the conductive layer 32L into portions corresponding to the plurality of wirings SOTL. One conductive layer 32 and the plurality of conductive layers 31 in contact with the one conductive layer 32 become one continuous film (that is, the conductive layer 30) through subsequent annealing treatment or the like.

The memory string MS is formed by the manufacturing process described above. The manufacturing process described above is just an example, and forming the memory string MS is not limited thereto. For example, other processing may be inserted between each manufacturing step, or some of the steps may be omitted or integrated. Each manufacturing step may be replaced by other processing.

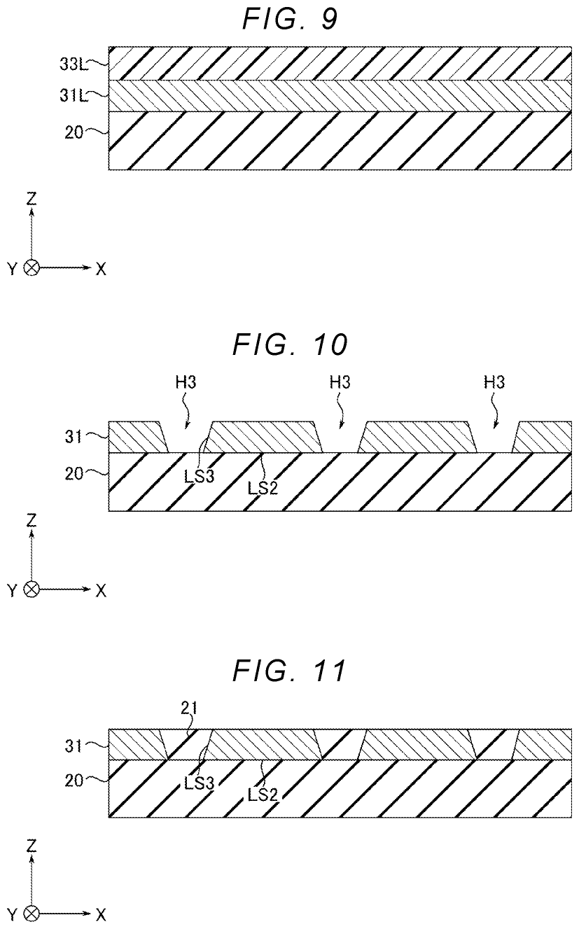

FIGS. 9 to 11 are cross-sectional views illustrating an example of a cross-sectional structure of a memory string according to a modification of the first embodiment during manufacture. FIGS. 9 to 11 illustrate an example of a process that may be substituted for the process of forming the conductive layer 31 described using FIGS. 5 and 6.

First, as illustrated in FIG. 9, the insulator layer 20, the conductive layer 31L, and a mask 33L are provided above the substrate in this order.

As illustrated in FIG. 10, a plurality of holes H3 penetrating the conductive layer 31L are formed by anisotropic etching. Accordingly, the conductive layer 31L is divided into a plurality of conductive layers 31. The bottom surface and side surface of each of the plurality of conductive layers 31 correspond to the second lower surface LS2 and the third lower surface LS3 of the wiring SOTL, respectively. The third lower surface LS3 formed in the step illustrated in FIG. 10 may have a direction opposite to that of the third lower surface LS3 formed in the step illustrated in FIG. 6.

Next, as illustrated in FIG. 11, the plurality of holes H3 are filled with the insulator layer 21. A portion of the insulator layer 21 above the portion where the plurality of holes H3 are filled therewith is removed by, for example, CMP. Accordingly, a structure equivalent to the structure described in FIG. 6 can be formed even by the substituted process.

### 1.3 Effects of First Embodiment

According to the first embodiment, the memory cell array 10 includes the memory string MS having a configuration in which a plurality of magnetoresistive effect elements MTJ are in contact with one wiring SOTL. When viewed in the Z-direction, the conductive layer 30 used as the wiring SOTL has a first portion that does not overlap with any of the plurality of element layers 40 each of which is used as the magnetoresistive effect element MTJ, a second portion that overlaps with the central region of the element layer 40, and a third portion that overlaps with the edge region of the element layer 40. The film thickness of the first portion and the film thickness of the third portion are thicker than the film thickness of the second portion. Accordingly, the resistance of the wiring portion is made lower than the resistance of the cell portion.

Additionally, in the process of etching the element layer 40, the upper part of the conductive layer 30 is etched together with the element layer 40. As a result, without the teachings of the first embodiment, there would be a concern that the film thickness of the wiring portion would become too thin, a current density of the wiring portion would increase, and a current density of the cell portion would decrease. An increase in the current density in the wiring portion is undesirable because it may cause disconnection of the wiring portion. In particular, since the film thickness tends to become thinnest at the boundary between the wiring portion and the cell portion, disconnection accompanying a local increase in current density is likely to occur. A decrease in current density in the cell portion is undesirable because it leads to an increase in write current.

According to the first embodiment, the conductive layer 30 includes the conductive layer 31 and the conductive layer 32. The conductive layer 31 is provided between adjacent clement layers 40 in the X-direction to be in contact with the lower surface of the conductive layer 32. Accordingly, even if a part of the conductive layer 32 is etched by IBE, the film thickness of the wiring portion remains thicker than that of the cell portion. Therefore, the risks associated with overly etching the conductive layer 30 by IBE are reduced.

A part of the upper surface of the conductive layer 31 is provided to overlap with the edge portion of the element layer 40 when viewed in the Z-direction. Accordingly, the film thickness of the conductive layer 30 is prevented from becoming too thin at the boundary between the cell portion and the wiring portion. Therefore, the occurrence of disconnection is prevented, and the increase in writing current is prevented.

### 2. Second Embodiment

Next, a magnetic memory device according to a second embodiment will be described. The second embodiment differs from the first embodiment in that the cell portion and the wiring portion of the wiring SOTL are formed of different materials. The following description will primarily discuss parts of the configuration and manufacturing method that are different from those of the first embodiment. Other parts of the configuration and manufacturing method that are the same as those of the first embodiment will be omitted as appropriate.

### 2.1 Configuration of Memory String

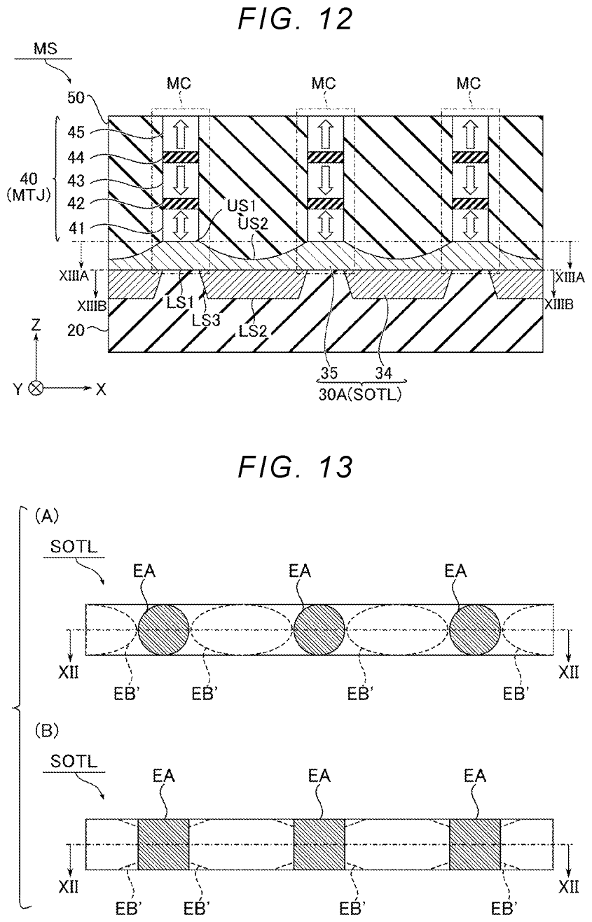

FIG. 12 is a cross-sectional view illustrating an example of a cross-sectional structure of a part of a memory string according to the second embodiment. FIG. 12 corresponds to FIG. 3 in the first embodiment. As illustrated in FIG. 12, the memory string MS according to the second embodiment includes a conductive layer 30A and the element layer 40. The configuration of the element layer 40 is the same as in the first embodiment.

On the upper surface of the insulator layer 20, the conductive layer 30A is provided. The conductive layer 30A extends in the X-direction. The conductive layer 30A is used as the wiring SOTL. A portion of the conductive layer 30A that overlaps with the element layer 40 when viewed in the Z-direction is used as the cell portion. A portion of the conductive layer 30A that does not overlap with the element layer 40 when viewed in the Z-direction is used as the wiring portion.

The lower surface of the conductive layer 30A includes the first lower surface LS1 that is substantially parallel to the XY plane, the second lower surface LS2 that is substantially parallel to the XY plane and located below the first lower surface LS1, and the third lower surface LS3 connecting the first lower surface LS1 and the second lower surface LS2. The first lower surface LS1 and the second lower surface LS2 are arranged to be repeated alternately in the X-direction. The upper surface of the conductive layer 30A includes the first upper surface US1 that is substantially parallel to the XY plane and the second upper surface US2 located below the first upper surface US1. The first upper surface US1 and the second upper surface US2 are arranged to be repeated alternately in the X-direction.

The conductive layer 30A is a stacked film including a conductive film that contains heavy metal having non-magnetism and conductivity and a conductive film having a lower resistance than the conductive film containing heavy metal. Specifically, the conductive layer 30A includes a plurality of conductive layers 34 and one conductive layer 35.

The plurality of conductive layers 34 are spaced apart from each other and arranged in the X-direction with the insulator layer 20 therebetween. The plurality of conductive layers 34 are provided instead of the plurality of conductive layers 31 in the first embodiment. That is, the bottom surface and the side surface of each of the plurality of conductive layers 34 correspond to the second lower surface LS2 and the third lower surface LS3 of the conductive layer 30A, respectively. The height at the upper surface of each of the plurality of conductive layers 34 matches the height at the top end of the insulating layer 20.

The conductive layer 34 is made of a material having a lower specific resistance than the conductive layer 35. Specifically, for example, the conductive layer 34 includes at least one element selected from tungsten (W), copper (Cu), aluminum (Al), and molybdenum (Mo). From the point of view of heat resistance, the conductive layer 34 preferably contains at least one clement selected from tungsten (W), copper (Cu), and molybdenum (Mo) among the elements described above.

The conductive layer 35 is in contact with the upper surface of each of the plurality of conductive layers 34. The material making up the conductive layer 35 is the same as the material making up the conductive layer 30 in the first embodiment. The conductive layer 35 generates spin orbit torque by the current flowing inside. The spin orbit torque acts on a portion of the element layer 40 that is in contact with the conductive layer 35.

The lower surface of the conductive layer 35 includes a portion in contact with the conductive layer 34 and a portion that is not in contact with the conductive layer 34 (is in contact with the insulator layer 20). The portion of the lower surface of the conductive layer 35 that is not in contact with the conductive layer 34 is the first lower surface LS1 of the conductive layer 30A.

The upper surface of the conductive layer 35 includes a portion in contact with the clement layer 40 and a portion that is not in contact with the element layer 40 (is in contact with the insulator layer 50). The portion of the upper surface of the conductive layer 35 that is in contact with the element layer 40 is the first upper surface US1 of the conductive layer 30A. The portion of the upper surface of the conductive layer 35 that is not in contact with the element layer 40 is the second upper surface US2 of the conductive layer 30A. The height at a portion located at the lowest position of the portion of the upper surface of the conductive layer 35 that is not in contact with the element layer 40 is located above the upper surface of the conductive layer 34. That is, the conductive layer 35 is provided not only in the cell portion of the conductive layer 30A but also in the wiring portion thereof. In other words, the wiring portion of the conductive layer 30A has a stacked structure of the conductive layers 34 and 35.

A resistance of a portion of the conductive layer 30A that overlaps with the second upper surface US2 when viewed in the Z-direction is designed to be lower than a resistance of a portion of the conductive layer 30A that overlaps with the first upper surface US1 when viewed in the Z-direction. As described above, a material whose resistance is lower than that of the conductive layer 35 is selected for the conductive layers 34. Therefore, in the second embodiment, as long as the condition that the resistance of the wiring portion of the conductive layer 30A is sufficiently lower than the resistance of the cell portion is satisfied, the film thickness of the wiring portion of the conductive layer 30A may be thicker or thinner than that of the cell portion.

FIG. 13 is a plan view illustrating two examples of shapes of a wiring and an element layer according to the second embodiment. FIG. 13 corresponds to FIG. 4 in the first embodiment. In FIG. 13, a line of intersection between the XIIIA-XIIIA plane of FIG. 12 and the conductive layer 30A (that is, the boundary between the first upper surface US1 and the second upper surface US2 when viewed in the Z-direction) is illustrated as a solid line EA. In FIG. 13, a line of intersection between the XIIIB-XIIIB plane in FIG. 12 and the conductive layer 30A (that is, the boundary between the first lower surface LS1 and the third lower surface LS3 when viewed in the Z-direction) is illustrated as a dotted line EB′. In the upper part (A) of FIG. 13, as a first example, a case is illustrated in which the solid line EA forms a circle and the dotted line EB′ forms an oval. In the lower part (B) of FIG. 13, as a second example, a case is illustrated in which the solid line EA forms a square and the dotted line EB′ forms substantially a rectangle. The cross section illustrated in FIG. 12 is the cross section of the memory string MS taken along line XII-XII illustrated in FIG. 13.

By making the resistance of the conductive layer 34 sufficiently lower than the resistance of the conductive layer 35, the condition that the resistance of the wiring portion of the conductive layer 30A is sufficiently lower than the resistance of the cell portion is satisfied. Here, in both the example in the upper part (A) of FIG. 13 and the example in the lower part (B) of FIG. 13, a part of the first upper surface US1 of the conductive layer 30A may not overlap with the region including the second lower surface LS2 and the third lower surface LS3 when viewed in the Z-direction.

### 2.2 Effects of Second Embodiment

According to the second embodiment, the conductive layer 30A is formed from a stacked film of the conductive layers 34 and 35. The conductive layer 35 is in contact with the element layer 40. The conductive layer 34 is provided between adjacent element layers 40 in the X-direction, on opposite sides of the conductive layer 35 as the element layer 40, and is in contact with the conductive layer 35. With such configuration, even if a part of the conductive layer 35 is etched by IBE, the film thickness of the wiring portion is made thicker than that of the cell portion. Therefore, the risks associated with overly etching the conductive layer 30A by IBE are reduced.

The conductive layer 34 contains at least one element selected from tungsten (W), copper (Cu), aluminum (Al), and molybdenum (Mo). Thus, the resistance of the conductive layer 34 is made sufficiently lower than the resistance of the conductive layer 35. Therefore, the resistance of the wiring portion is lowered more than when the conductive layer 35 is not used. Accordingly, similarly to the first embodiment, the occurrence of disconnection is prevented and the increase in write current is prevented.

### 2.3 Modification of Second Embodiment

In the second embodiment described above, a case has been described in which the wiring portion of the wiring SOTL has a stacked structure including a portion having the same resistance as the cell portion and a portion having a lower resistance than the cell portion, but the second embodiment is not limited thereto. For example, the wiring portion of the wiring SOTL may not have the portion having the same resistance as the cell portion. The following description will primarily discuss parts of the configuration and the manufacturing method that are different from the second embodiment. Other parts of the configuration and manufacturing method that are the same as those of the second embodiment will be omitted as appropriate.

FIG. 14 is a cross-sectional view illustrating an example of a cross-sectional structure of a part of a memory string according to a modification of the second embodiment. FIG. 14 corresponds to FIG. 12 in the second embodiment. As illustrated in FIG. 14, the memory string MS according to the modification of the second embodiment includes a conductive layer 30B and the element layer 40. The configuration of the element layer 40 is the same as that in the second embodiment.

On the upper surface of the insulator layer 20, the conductive layer 30B is provided. The conductive layer 30B extends in the X-direction. The conductive layer 30B is used as the wiring SOTL. A portion of the conductive layer 30B that overlaps with the element layer 40 when viewed in the Z-direction is used as the cell portion. A portion of the conductive layer 30B that does not overlap with the element layer 40 when viewed in the Z-direction is used as the wiring portion.

The lower surface of the conductive layer 30B includes the first lower surface LS1 that is substantially parallel to the XY plane, the second lower surface LS2 that is substantially parallel to the XY plane and located below the first lower surface LS1, and the third lower surface LS3 connecting the first lower surface LS1 and the second lower surface LS2. The first lower surface LS1 and the second lower surface LS2 are arranged to be repeated alternately in the X-direction. The upper surface of the conductive layer 30B includes the first upper surface US1 that is substantially parallel to the XY plane and the second upper surface US2 located below the first upper surface US1. The first upper surface US1 and the second upper surface US2 are arranged to be repeated alternately in the X-direction.

The conductive layer 30B is a stacked film including a conductive film that contains heavy metal having non-magnetism and conductivity and a conductive film having a lower resistance than the conductive film containing heavy metal. Specifically, the conductive layer 30B includes a plurality of conductive layers 36 and a plurality of conductive layers 37.

The material making up the plurality of conductive layers 36 is the same as the material making up the plurality of conductive layers 34 in the second embodiment. The plurality of conductive layers 36 are spaced apart from each other and arranged in the X-direction with the insulator layer 20 therebetween. That is, the bottom surface and the side surface of each of the plurality of conductive layers 36 correspond to the second lower surface LS2 and the third lower surface LS3 of the conductive layer 30B, respectively. The upper surface of each of the plurality of conductive layers 36 includes a portion in contact with the conductive layer 37 and a portion that is not in contact with the conductive layer 37 (is in contact with the insulator layer 50). A portion of the upper surface of the conductive layer 36 that is not in contact with the conductive layer 37 is a part of the second upper surface US2 of the conductive layer 30B. The portion of the upper surface of the conductive layer 36 that is not in contact with the conductive layer 37 is located (recessed) below the portion of the upper surface of the conductive layer 36 that is in contact with the conductive layer 37. A recess in the upper part of the conductive layer 36 is filled with the insulator layer 50 along with the spaces between the plurality of conductive layers 37.

The conductive layer 37 is in contact with a part of the upper surface of each of two conductive layers 36 adjacent to each other in the X-direction. The plurality of conductive layers 37 are spaced apart from each other and arranged in the X-direction with the insulator layer 50 therebetween. The material making up the conductive layer 37 is the same as the material making up the conductive layer 35 in the second embodiment. The conductive layer 37 generates spin orbit torque by the current flowing inside. The spin orbit torque acts on a portion of the element layer 40 that is in contact with the conductive layer 37.

The lower surface of the conductive layer 37 includes a portion in contact with two conductive layers 36 and a portion that is not in contact with any conductive layers 36 (is in contact with the insulator layer 20). A portion of the lower surface of the conductive layer 37 that is not in contact with the conductive layer 36 is the first lower surface LS1 of the conductive layer 30B.

The upper surface of the conductive layer 37 includes a portion in contact with the clement layer 40 and a portion that is not in contact with the element layer 40 (is in contact with the insulator layer 50). The portion of the upper surface of the conductive layer 37 that is in contact with the element layer 40 is the first upper surface US1 of the conductive layer 30B. The portion of the upper surface of the conductive layer 37 that is not in contact with the element layer 40 is a part of the second upper surface US2 of the conductive layer 30B.

The wiring portion of the conductive layer 30B formed as described above does not include a material having a relatively high specific resistance, such as one of those used to generate spin orbit torque. Therefore, the current density in the wiring portion is further reduced.

### 3. Third Embodiment

Next, a magnetic memory device according to a third embodiment will be described. The third embodiment differs from the first and second embodiments in that the wiring SOTL is provided above the magnetoresistive effect element MTJ. The following description will primarily discuss parts of the configuration and manufacturing method that are different from the first embodiment. Other parts of the configuration and manufacturing method that are the same as those of the first embodiment will be omitted as appropriate.

### 3.1 Configuration of Memory String

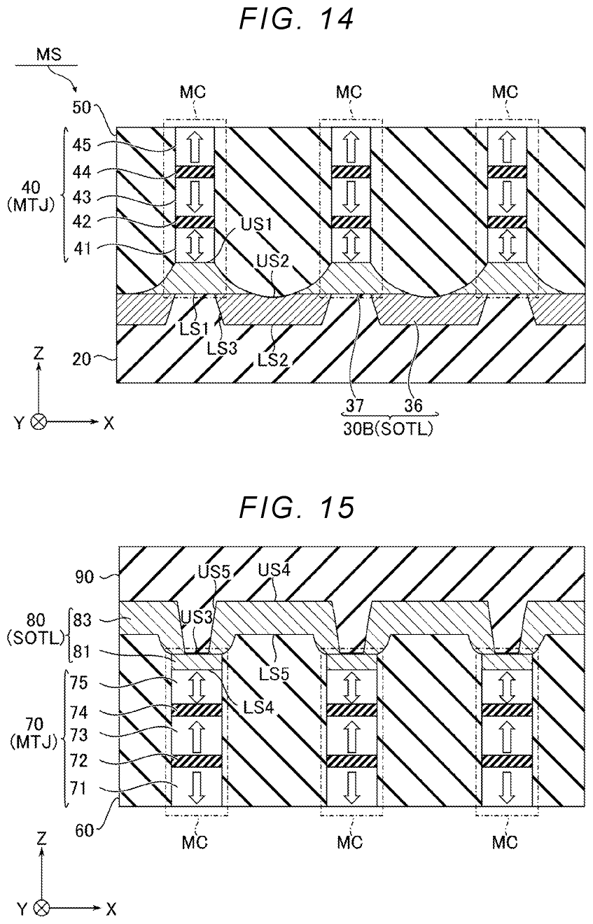

FIG. 15 is a cross-sectional view illustrating an example of a cross-sectional structure of a part of a memory string according to the third embodiment. FIG. 15 corresponds to FIG. 3 in the first embodiment. As illustrated in FIG. 15, the memory string MS according to the third embodiment includes an element layer 70 and a conductive layer 80.

The element layer 70 is provided above the substrate. The element layer 70 has a columnar shape extending in the Z-direction. The side surfaces of the element layer 70 are covered with an insulator layer 60.

The element layer 70 is used as the magnetoresistive effect element MTJ. The element layer 70 has the same configuration as the element layer 40 in the first embodiment, but upside down. Specifically, the element layer 70 includes a ferromagnetic layer 71, a nonmagnetic layer 72, a ferromagnetic layer 73, a nonmagnetic layer 74, and a ferromagnetic layer 75. The ferromagnetic layer 71, the nonmagnetic layer 72, the ferromagnetic layer 73, the nonmagnetic layer 74, and the ferromagnetic layer 75 are stacked in this order from bottom to top in the Z-direction. That is, the element layer 70 extends in the Z-direction.

The ferromagnetic layer 71 is a conductive film having ferromagnetism. The ferromagnetic layer 71 is used as the shift cancelling layer.

On the upper surface of the ferromagnetic layer 71, the nonmagnetic layer 72 is provided. The nonmagnetic layer 72 is a conductive film having non-magnetism. The nonmagnetic layer 72 is used as the spacer layer.

On the upper surface of the nonmagnetic layer 72, the ferromagnetic layer 73 is provided. The ferromagnetic layer 73 is a conductive film having ferromagnetism. The ferromagnetic layer 73 is used as the reference layer.

On the upper surface of the ferromagnetic layer 73, the nonmagnetic layer 74 is provided. The nonmagnetic layer 74 is a conductive film having non-magnetism. The nonmagnetic layer 74 is used as the tunnel barrier layer.

On the upper surface of the nonmagnetic layer 74, the ferromagnetic layer 75 is provided. The ferromagnetic layer 75 is a conductive film having ferromagnetism. The ferromagnetic layer 75 is used as the storage layer.

The conductive layer 80 is in contact with the upper surface of the ferromagnetic layer 75. The conductive layer 80 extends in the X-direction. The conductive layer 80 is used as the wiring SOTL. A portion of the conductive layer 80 that overlaps with the element layer 70 when viewed in the Z-direction is used as the cell portion. A portion of the conductive layer 80 that does not overlap with the element layer 70 when viewed in the Z-direction is used as the wiring portion.

The conductive layer 80 is a continuous film containing heavy metal having non-magnetism and conductivity. The material making up the conductive layer 80 is the same as the material making up the conductive layer 30 in the first embodiment. The conductive layer 80 generates spin orbit torque by the current flowing inside. The spin orbit torque acts on the ferromagnetic layer 75.

The upper surface of the conductive layer 80 includes a third upper surface US3 that is substantially parallel to the XY plane, a fourth upper surface US4 that is substantially parallel to the XY plane and located above the third upper surface US3, and a fifth upper surface US5 that connects the third upper surface US3 and the fourth upper surface US4. The third upper surface US3 and the fourth upper surface US4 are arranged to be repeated alternately in the X-direction. The lower surface of the conductive layer 80 includes a fourth lower surface LS4 that is substantially parallel to the XY plane and a fifth lower surface LS5 located above the fourth lower surface LS4. The fourth lower surface LS4 and the fifth lower surface LS5 are arranged to be repeated alternately in the X-direction. A part of the fourth lower surface LS4 overlaps with a region including the fourth upper surface US4 and the fifth upper surface US5 when viewed in the Z-direction.

The film thickness of the conductive layer 80 is the thinnest in the portion where the third upper surface US3 and the fourth lower surface LS4 overlap when viewed in the Z-direction. The film thickness of the conductive layer 80 in the portion where the fourth upper surface US4 and the fifth upper surface US5 overlap the fourth lower surface LS4 when viewed in the Z-direction is thicker than the film thickness of the conductive layer 80 in the portion where the third upper surface US3 and the fourth lower surface LS4 overlap when viewed in the Z-direction. The film thickness of the conductive layer 80 in the portion where the fourth upper surface US4 and the fifth lower surface LS5 overlap when viewed in the Z-direction is thicker, than the film thickness of the conductive layer 80 in the portion where the fourth upper surface US4 and the fifth upper surface US5 overlap the fourth lower surface LS4 when viewed in the Z-direction. The film thickness of the conductive layer 80 becomes thickest at the portion where the fourth upper surface US4 and the fifth lower surface LS5 overlap when viewed in the Z-direction. That is, the film thickness of the wiring portion of the wiring SOTL is thicker than the film thickness of the cell portion.

The conductive layer 80 can also be said to have a stacked structure of conductive layers 81 and 83. The conductive layer 81 is a portion of the conductive layer 80 below the third upper surface US3. The conductive layer 83 is a portion of the conductive layer 80 above the third upper surface US3.

### 3.2 Method for Manufacturing Memory String

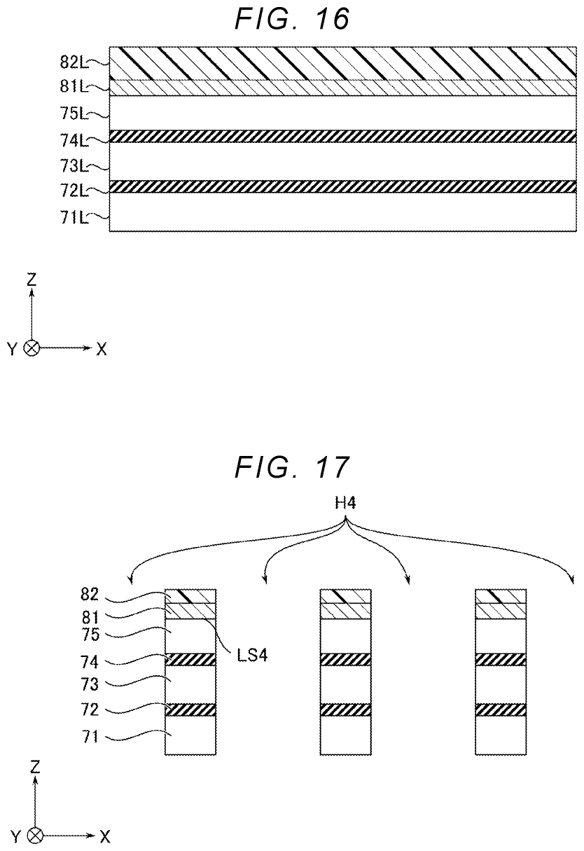

FIGS. 16 to 21 are cross-sectional views illustrating an example of a cross-sectional structure of the memory string according to the third embodiment during manufacture.

First, as illustrated in FIG. 16, a ferromagnetic layer 71L, a nonmagnetic layer 72L, a ferromagnetic layer 73L, a nonmagnetic layer 74L, a ferromagnetic layer 75L, a conductive layer 81L, and a mask 82L are provided above the substrate in this order. The ferromagnetic layer 71L contains the same material as the ferromagnetic layer 71. The nonmagnetic layer 72L contains the same material as the nonmagnetic layer 72. The ferromagnetic layer 73L contains the same material as the ferromagnetic layer 73. The nonmagnetic layer 74L contains the same material as the nonmagnetic layer 74. The ferromagnetic layer 75L contains the same material as the ferromagnetic layer 75. The conductive layer 81L contains the same material as the conductive layer 80.

As illustrated in FIG. 17, the mask 82L is processed into a plurality of masks 82 corresponding to the plurality of magnetoresistive effect elements MTJ. Thereafter, the ferromagnetic layer 71L, the nonmagnetic layer 72L, the ferromagnetic layer 73L, the nonmagnetic layer 74L, the ferromagnetic layer 75L, and the conductive layer 81L are etched by anisotropic etching to form a plurality of stacked bodies. Each of the plurality of stacked bodies includes the ferromagnetic layer 71, the nonmagnetic layer 72, the ferromagnetic layer 73, the nonmagnetic layer 74, the ferromagnetic layer 75, and the conductive layer 81, which are stacked in this order from bottom to top. The lower surface of the conductive layer 81 is the fourth lower surface LS4 of the wiring SOTL. The plurality of stacked bodies are arranged apart from each other when viewed in the Z-direction. For example, IBE is used for the anisotropic etching in the current step. One continuous hole H4 is formed between the plurality of stacked bodies.

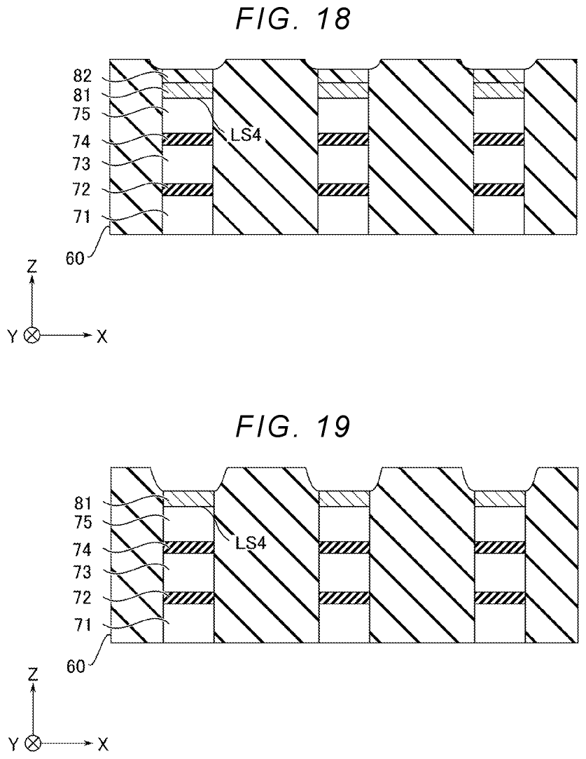

Next, as illustrated in FIG. 18, the hole H4 is filled with the insulator layer 60. A portion of the insulator layer 60 above the mask 82 is removed by, for example, CMP. Accordingly, the upper surface of the mask 82 is exposed.

Next, as illustrated in FIG. 19, the mask 82 is removed. Accordingly, the upper surface of the conductive layer 81 is exposed.

Next, as illustrated in FIG. 20, a conductive layer 83L is provided on the upper surfaces of the insulator layer 60 and the conductive layer 81. The conductive layer 83L contains the same material as the conductive layer 80.

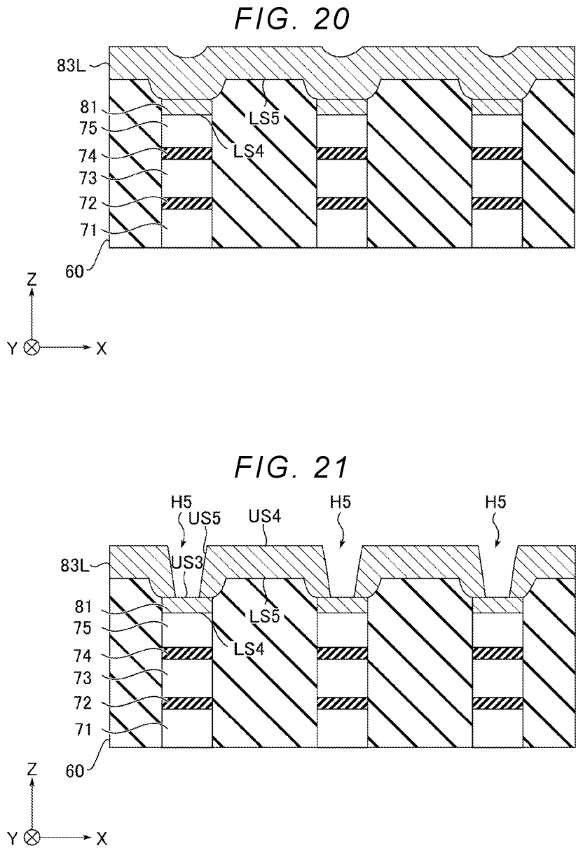

As illustrated in FIG. 21, the conductive layer 83L is etched by anisotropic etching to form a plurality of holes H5. A portion of the conductive layer 81 is exposed on the bottom surface of each of the plurality of holes H5. The conductive layer 81 exposed on the bottom surfaces of the plurality of holes H5 is the third upper surface US3 of the wiring SOTL. The conductive layer 83L exposed on the side surfaces of the plurality of holes H5 is the fifth upper surface US5 of the wiring SOTL. A portion of the upper surface of the conductive layer 83L between the holes H5 arranged in the X-direction is the fourth upper surface US4 of the wiring SOTL. A part of the upper surface of the conductive layer 83L is provided to overlap with an edge of the region where the magnetoresistive effect element MTJ is provided when viewed in the Z-direction.

Thereafter, a plurality of conductive layers 83 are formed by dividing the conductive layer 83L into portions corresponding to the plurality of wirings SOTL. One conductive layer 83 and the plurality of conductive layers 81 in contact with the one conductive layer 83 become one continuous film (that is, the conductive layer 80) through subsequent annealing treatment or the like.

The memory string MS is formed by the manufacturing process described above.

### 3.3 Effects of Third Embodiment

According to the third embodiment, the conductive layer 80 includes a first portion that does not overlap with any of the plurality of element layers 70, a second portion that overlaps with a central region of the element layer 70, and a third portion that overlaps with an edge region of the element layer 70 when viewed in the Z-direction. The film thickness of the first portion and the film thickness of the third portion are each thicker than the film thickness of the second portion. Accordingly, the resistance of the wiring portion is made lower than that of the cell portion.

The conductive layer 80 includes the conductive layer 81 and the conductive layer 83. The conductive layer 81 is in contact with the upper surface of the element layer 70. The conductive layer 83 is formed by being provided to electrically connect the upper surface of each of the plurality of conductive layers 81 arranged in the X-direction, and then partially etching the portion which overlaps with the element layer 70 when viewed in the Z-direction. Accordingly, the film thickness of the wiring portion is made thicker than the film thickness of the cell portion. A part of the upper surface of the conductive layer 83 is provided to overlap with the edge portion of the element layer 70 when viewed in the Z-direction. Accordingly, the thickness of the conductive layer 80 is prevented from becoming too thin at the boundary between the cell portion and the wiring portion. Therefore, the occurrence of disconnection is prevented, and the increase in writing current is prevented.

### 4. Fourth Embodiment

Next, a magnetic memory device according to a fourth embodiment will be described. The fourth embodiment differs from the third embodiment in that the cell portion and the wiring portion of the wiring SOTL are formed of different materials. The following description will primarily discuss parts of the configuration and manufacturing method that are different from those of the third embodiment. Other parts of the configuration and manufacturing method that are the same as those of the third embodiment will be omitted as appropriate.

### 4.1 Configuration of Memory String

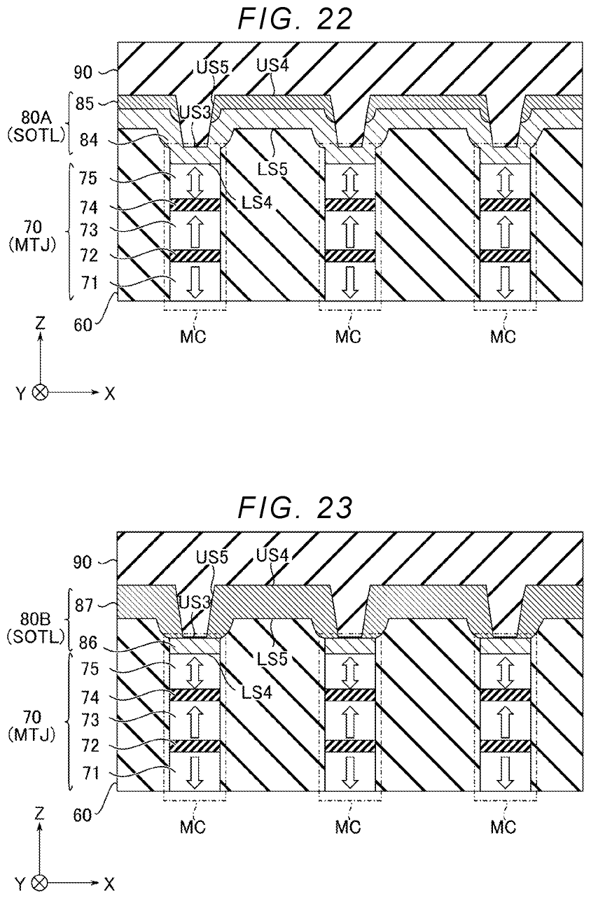

FIG. 22 is a cross-sectional view illustrating an example of a cross-sectional structure of a part of the memory string according to the fourth embodiment. FIG. 22 corresponds to FIG. 15 in the third embodiment. As illustrated in FIG. 22, the memory string MS according to the fourth embodiment includes a conductive layer 80A and the element layer 70. The configuration of the element layer 70 is the same as that in the third embodiment.

The conductive layer 80A is in contact with the upper surface of each of the plurality of clement layers 70. The conductive layer 80A extends in the X-direction. The conductive layer 80A is used as the wiring SOTL. A portion of the conductive layer 80A that overlaps with the element layer 70 when viewed in the Z-direction is used as the cell portion. A portion of the conductive layer 80A that does not overlap with the element layer 70 when viewed in the Z-direction is used as the wiring portion.

The upper surface of the conductive layer 80A includes the third upper surface US3 that is substantially parallel to the XY plane, the fourth upper surface US4 that is substantially parallel to the XY plane and located above the third upper surface US3, and the fifth upper surface US5 that connects the third upper surface US3 and the fourth upper surface US4. The third upper surface US3 and the fourth upper surface US4 are arranged to be repeated alternately in the X-direction. The lower surface of the conductive layer 80A includes the fourth lower surface LS4 that is substantially parallel to the XY plane and the fifth lower surface LS5 located above the fourth lower surface LS4. The fourth lower surface LS4 and the fifth lower surface LS5 are arranged to be repeated alternately in the X-direction.

The conductive layer 80A is a stacked film including a conductive film that contains heavy metal having non-magnetism and conductivity and a conductive film having a lower resistance than the conductive film that contains heavy metal. Specifically, the conductive layer 80A includes one conductive layer 84 and a plurality of conductive layers 85.

The conductive layer 84 extends in the X-direction to be in contact with the upper surface of each of the plurality of element layers 70 arranged in the X-direction. That is, the bottom surface of the conductive layer 84 has a portion that is in contact with the ferromagnetic layer 75 and a portion that is not in contact with the ferromagnetic layer 75. A portion of the bottom surface of the conductive layer 84 that is in contact with the ferromagnetic layer 75 is the fourth lower surface LS4 of the conductive layer 80A. A portion of the bottom surface of the conductive layer 84 that is not in contact with the ferromagnetic layer 75 is the fifth lower surface LS5 of the conductive layer 80A. A portion of the upper surface of the conductive layer 84 that overlaps with the central portion of the element layer 70 when viewed in the Z-direction is the third upper surface US3 of the conductive layer 80A. The material making up the conductive layer 84 is the same as the material making up the conductive layer 80 in the third embodiment. The conductive layer 84 generates spin orbit torque by the current flowing inside. The spin orbit torque acts on the ferromagnetic layer 75.

On the upper surface of the conductive layer 84, a plurality of conductive layers 85 are provided. The plurality of conductive layers 85 are spaced apart from each other and arranged in the X-direction. Each of the plurality of conductive layers 85 overlaps with any of the plurality of element layers 70 when viewed in the Z-direction. Each of the plurality of conductive layers 85 may or may not overlap with the edge portion of the element layer 70 when viewed in the Z-direction. The upper surface of each of the plurality of conductive layers 85 is the fourth upper surface US4 and the fifth upper surface US5 of the conductive layer 80A.

The conductive layer 85 is made of a material having a lower specific resistance than that of the conductive layer 84. Specifically, for example, the conductive layer 85 includes at least one element selected from tungsten (W), copper (Cu), aluminum (Al), and molybdenum (Mo). From the point of view of heat resistance, the conductive layer 85 preferably contains at least one element selected from tungsten (W), copper (Cu), and molybdenum (Mo) among the elements described above.

The resistance of the portion of the conductive layer 80A that overlaps with the fifth lower surface LS5 when viewed in the Z-direction is designed to be lower than the resistance of the portion of the conductive layer 80A that overlaps with the fourth lower surface LS4 when viewed in the Z-direction. As described above, a material having lower resistance than that of the conductive layer 84 is selected for the conductive layer 85. Therefore, in the fourth embodiment, if the condition that the resistance of the wiring portion of the conductive layer 80A is sufficiently lower than the resistance of the cell portion is satisfied, the film thickness of the wiring portion of the conductive layer 80A may be thicker or thinner than that of the cell portion.

### 4.2 Effects of Fourth Embodiment

According to the fourth embodiment, the conductive layer 80A is formed from a stacked film of the conductive layers 84 and 85. The conductive layer 84 is in contact with the element layer 70. The conductive layer 85 is provided between adjacent element layers 70 in the X-direction on the side opposite to the conductive layer 84 with respect to the element layer 70, and is in contact with the conductive layer 84. Accordingly, the film thickness of the wiring portion is made thicker than that of the cell portion.

The conductive layer 85 includes at least one element selected from tungsten (W), copper (Cu), aluminum (Al), and molybdenum (Mo). Accordingly, the resistance of the conductive layer 85 is made sufficiently lower than the resistance of the conductive layer 84. Therefore, the resistance of the wiring portion is made lower than when the conductive layer 85 is not used. Accordingly, similarly to the third embodiment, the occurrence of disconnection is prevented and the increase in write current is prevented.

### 4.3 Modification of Fourth Embodiment

In the fourth embodiment described above, a case has been described in which the wiring portion of the wiring SOTL has a stacked structure including a portion having the same resistance as the cell portion and a portion having a lower resistance than the cell portion, but is not limited thereto. For example, the wiring portion of the wiring SOTL may not have a portion having the same resistance as the cell portion. The following description will primarily discuss parts of the configuration and manufacturing method that are different from those of the fourth embodiment. Other parts of the configuration and manufacturing method that are the same as those of the fourth embodiment will be omitted as appropriate.

FIG. 23 is a cross-sectional view illustrating an example of a cross-sectional structure of a part of a memory string according to a modification of the fourth embodiment. FIG. 23 corresponds to FIG. 22 in the fourth embodiment. As illustrated in FIG. 23, the memory string MS according to the modification of the fourth embodiment includes a conductive layer 80B and the element layer 70. The configuration of the element layer 70 is the same as that of the fourth embodiment.

The conductive layer 80B is in contact with the upper surface of each of the plurality of element layers 70. The conductive layer 80B extends in the X-direction. The conductive layer 80B is used as the wiring SOTL. A portion of the conductive layer 80B that overlaps with the element layer 70 when viewed in the Z-direction is used as the cell portion. A portion of the conductive layer 80B that does not overlap with the element layer 70 when viewed in the Z-direction is used as the wiring portion.

The upper surface of the conductive layer 80B includes the third upper surface US3 that is substantially parallel to the XY plane, the fourth upper surface US4 that is substantially parallel to the XY plane and located above the third upper surface US3, and the fifth upper surface US5 that connects the third upper surface US3 and the fourth upper surface US4. The third upper surface US3 and the fourth upper surface US4 are arranged to be repeated alternately in the X-direction. The lower surface of the conductive layer 80B includes the fourth lower surface LS4 that is substantially parallel to the XY plane and the fifth lower surface LS5 located above the fourth lower surface LS4. The fourth lower surface LS4 and the fifth lower surface LS5 are arranged to be repeated alternately in the X-direction.

The conductive layer 80B is a stacked film including a conductive film that contains heavy metal having non-magnetism and conductivity and a conductive film having a lower resistance than the conductive film containing heavy metal. Specifically, the conductive layer 80B includes a plurality of conductive layers 86 and a plurality of conductive layers 87.

Each of the plurality of conductive layers 86 is provided on the upper surface of the corresponding element layer 70. The bottom surface of each of the plurality of conductive layers 86 is the fourth lower surface LS4 of the conductive layer 80B. On the upper surface of each of the plurality of conductive layers 86, a portion that overlaps with the central portion of the element layer 70 when viewed in the Z-direction is the third upper surface US3 of the conductive layer 80B. The material making up the conductive layer 86 is the same as the material making up the conductive layer 84 in the fourth embodiment. The conductive layer 86 generates spin orbit torque by the current flowing inside. The spin orbit torque acts on the ferromagnetic layer 75.

The conductive layer 87 connects the conductive layers 86 adjacent to each other in the X-direction. The conductive layer 87 has a portion that does not overlap with any of the clement layers 70 adjacent in the X-direction and a portion that is in contact with the edge portion of the element layer 70. Of the bottom surface of each of the plurality of conductive layers 87, a portion that does not overlap with the element layer 70 when viewed in the Z-direction is the fifth lower surface LS5 of the conductive layer 80B. The upper surface of each of the plurality of conductive layers 87 is the fourth upper surface US4 and the fifth upper surface US5 of the conductive layer 80B. The material making up the plurality of conductive layers 87 is the same as the material making up the conductive layer 85 in the fourth embodiment.

The wiring portion of the conductive layer 80B formed as described above does not include a material having a relatively high specific resistance, such as one of those used to generate spin orbit torque. Therefore, the current density in the wiring portion is further reduced.

### 5. Others

The embodiments described above are not limited to the examples described above, and various modifications may be applied thereto.

In the embodiments described above, the case in which the three-terminal type switching element is the switching element SEL2 has been described, but embodiments are not limited thereto. For example, a two-terminal type switching element may be the switching element SEL2. When the voltage applied between two terminals is less than a threshold voltage Vth, the two-terminal type switching element SEL2 goes into a “high resistance” state or an “off” state (to an electrically non-conducting state). When the voltage applied between the two terminals is equal to or higher than the threshold voltage Vth, the two-terminal switching element SEL2 changes to a “low resistance” state or an “on” state (to an electrically conductive state). Regardless of the polarity of the voltage applied between the two terminals (regardless of the direction of the flowing current), the two-terminal type switching element SEL2 can switch whether a current is made to flow or cut off according to the magnitude of the voltage applied to the corresponding memory cell MC.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A magnetic memory device comprising:
a first conductive layer; and
a first magnetoresistive effect element and a second magnetoresistive effect element that each extends in a first direction, are provided apart from each other in a second direction crossing the first direction, and are each in contact with the first conductive layer, wherein
the first conductive layer includes
a first portion that does not overlap with any of the first magnetoresistive effect element and the second magnetoresistive effect element when viewed in the first direction,
a second portion that overlaps with a central region of the first magnetoresistive effect element when viewed in the first direction, and
a third portion that overlaps with an edge region of the first magnetoresistive effect element when viewed in the first direction.

2. The magnetic memory device according to claim 1, wherein a film thickness of the first portion of the first conductive layer and a film thickness of the third portion of the first conductive layer are thicker than a film thickness of the second portion of the first conductive layer.

3. The magnetic memory device according to claim 1, wherein the first conductive layer contains at least one element selected from tantalum (Ta), tungsten (W), rhenium (Re), ruthenium (Ru), rhodium (Rh), palladium (Pd), silver (Ag), copper (Cu), osmium (Os), iridium (Ir), platinum (Pt), gold (Au), manganese (Mn), lead (Pb), bismuth (Bi), antimony (Sb), tellurium (Te), selenium (Se), and polonium (Po).

4. The magnetic memory device according to claim 1, wherein the first conductive layer is formed from a single conductive layer.

5. The magnetic memory device according to claim 1, wherein the first conductive layer is formed by stacking a plurality of conductive layers.

6. The magnetic memory device according to claim 1, wherein the first magnetoresistive effect element includes:
a first ferromagnetic layer in contact with the first conductive layer,
a second ferromagnetic layer located on the opposite side of the first ferromagnetic layer, as the first conductive layer , and
a nonmagnetic layer located between the first ferromagnetic layer and the second ferromagnetic layer.

7. The magnetic memory device according to claim 1, further comprising:
a substrate on which the first conductive layer, the first magnetoresistive effect element, and the second magnetoresistive effect element are provided, wherein
the first magnetoresistive effect element and the second magnetoresistive effect element are located on the opposite side of the first conductive layer, as the substrate.

8. The magnetic memory device according to claim 1, further comprising:
a substrate on which the first conductive layer, the first magnetoresistive effect element, and the second magnetoresistive effect element are provided, wherein
the first magnetoresistive effect element and the second magnetoresistive effect element are provided between the substrate and the first conductive layer.

9. The magnetic memory device according to claim 1, wherein a resistance of the first portion of the first conductive layer and a resistance of the third portion of the first conductive layer are each lower than a resistance of the second portion of the first conductive layer.

10. A magnetic memory device comprising:
a stacked film; and
a first magnetoresistive effect element and a second magnetoresistive effect element that are provided apart from each other and that are each in contact with the stacked film, wherein
the stacked film includes
a first conductive layer in contact with the first magnetoresistive effect element, and
a second conductive layer that is provided between the first magnetoresistive effect element and the second magnetoresistive effect element, that is on the opposite side of the first conductive layer as the first magnetoresistive effect element and the second magnetoresistive effect element, and that is in contact with the first conductive layer, and
a resistance of the second conductive layer is lower than a resistance of the first conductive layer.

11. The magnetic memory device according to claim 10, wherein the first conductive layer is further in contact with the second magnetoresistive effect element.

12. The magnetic memory device according to claim 10, wherein
the stacked film further includes a third conductive layer provided in contact with the second magnetoresistive effect element and apart from the first conductive layer, and
the second conductive layer is in contact with each of the first conductive layer and the third conductive layer.

13. The magnetic memory device according to claim 12, wherein the first conductive layer and the third conductive layer are electrically connected to each other via the second conductive layer.

14. The magnetic memory device according to claim 10, wherein
the first magnetoresistive effect element and the second magnetoresistive effect element each extends in a first direction, and
the first conductive layer includes a portion that overlaps with both the first magnetoresistive effect element and the second conductive layer when viewed in the first direction.

15. The magnetic memory device according to claim 10, wherein the first conductive layer contains at least one element selected from tantalum (Ta), tungsten (W), rhenium (Re), ruthenium (Ru), rhodium (Rh), palladium (Pd), silver (Ag), copper (Cu), osmium (Os), iridium (Ir), platinum (Pt), gold (Au), manganese (Mn), lead (Pb), bismuth (Bi), antimony (Sb), tellurium (Te), selenium (Se), and polonium (Po).

16. The magnetic memory device according to claim 10, wherein the first conductive layer is formed from a single conductive layer.

17. The magnetic memory device according to claim 10, wherein the second conductive layer contains at least one element selected from tungsten (W), copper (Cu), aluminum (Al), and molybdenum (Mo).

18. The magnetic memory device according to claim 10, wherein the first magnetoresistive effect element includes
a first ferromagnetic layer in contact with the first conductive layer,
a second ferromagnetic layer located on the opposite side of the first ferromagnetic layer as the first conductive layer, and
a nonmagnetic layer located between the first ferromagnetic layer and the second ferromagnetic layer.

19. The magnetic memory device according to claim 10, further comprising:
a substrate on which the stacked film, the first magnetoresistive effect element, and the second magnetoresistive effect element are provided, wherein
the first magnetoresistive effect element and the second magnetoresistive effect element are located on the opposite side of the stacked film as the substrate.

20. The magnetic memory device according to claim 19, wherein the first magnetoresistive effect element and the second magnetoresistive effect element are provided between the substrate and the stacked film.
